(19) United States
(12) Patent Application Publication
(10) Pub. No.: US 2014/0087562 A1
(43) Pub. Date: Mar. 27, 2014

(54) METHOD FOR PROCESSING SILICON SUBSTRATE AND METHOD FOR PRODUCING CHARGED-PARTICLE BEAM LENS

(71) Applicant: Canon Kabushiki Kaisha, Tokyo (JP)

(72) Inventor: Yoichi Ikarashi, Fujisawa-shi (JP)

(73) Assignee: Canon Kabushiki Kaisha, Tokyo (JP)

(21) Appl. No.: 14/029,447

(22) Filed: Sep. 17, 2013

(30) Foreign Application Priority Data
Sep. 21, 2012 (JP) 2012-207793

(51) Int. Cl. H01L 21/768; H01L 21/3065; H01L 21/027

(52) U.S. Cl. CPC H01L 21/76898; H01L 21/027; H01L 21/30655
USPC 438/697

(57) ABSTRACT

A method for processing a silicon substrate includes forming a mask layer on the silicon substrate; forming a hole is farmed in the silicon substrate by alternately repeating (i) an etching step in which plasma etching is performed in a thickness direction of the silicon substrate using the mask layer as a mask and (ii) a deposition step in which a protection film is deposited on an inner wall of the hole formed in the etching step; removing the protection film; and a planarizing a side wall of the hole by etching the inner wall of the hole from which the protection film has been removed. The mask layer includes a material that withstands the removal step. In the planarization step, the inner wall of the hole is etched using the mask layer as a mask.

### BACKGROUND OF THE INVENTION

1. Field of the Invention

The present invention relates to a method for processing a silicon substrate and a method for producing a charged-particle beam lens and particularly relates to a method for planarizing the side wall of a hole formed in the silicon substrate.

2. Description of the Related Art

A known method for forming a hole in a silicon substrate is the Bosch process, which is a process including the following steps repeated alternately: an etching step in which the silicon substrate is subjected to plasma etching and a deposition step in which a protection film is deposited on the inner wall of a hole formed in the etching step. In the Bosch process, SF₆ is used as an etching gas and C₄F₈ is used as a deposition gas. By using the Bosch process, a hole with a large aspect ratio can be vertically formed in a silicon substrate.

However, when a hole is formed by the Bosch process, as shown in FIG. 7, wave-like irregularities called “scallops” are formed on a side wall 3′ of a hole 3 formed in a silicon substrate 1 due to isotropic etching performed in the etching step.

For example, in charged-particle beam exposure technique, the optical aberration of a charged-particle beam lens, which is an optical element, mainly determines the limit of fine patterning. Optical aberration is highly affected by the dimensional accuracy of a hole formed in an electrode substrate of the charged-particle beam lens. In particular, when the opening of the hole has a circular shape, optical aberration is highly affected by parameters related to the symmetry of the opening shape, such as circularity, and a highly accurate circularity of a few nanometers to several tens of nanometers is required. However, when the size of the irregularities (scallops) is several hundred nanometers, such a required accuracy of circularity may not be achieved.

Moreover, when a conductive material is deposited by sputtering to form a seed layer on the inner wall of a hole in, for example, a via-hole formation process for semiconductor devices, the irregularities (scallops) cause the thickness of the sputtering film to be nonuniform, which may result in the formation of defectively coated portions.

Japanese Patent Laid-Open No. 2007-311584 discloses a method for planarizing the scallops, the method including forming a hole by the Bosch process, subsequently removing a mask layer, and then performing dry-etching. Japanese Patent Laid-Open No. 2005-142265 discloses a method for planarizing scallops, the method including performing an annealing treatment in a hydrogen ambient atmosphere.

Shortening the cycle time between the etching step and the deposition step reduces the size of scallops. However, the reduction in the size of scallops may not always be entirely satisfactory. In addition, the processing time is disadvantageously prolonged.

In the method described in Japanese Patent Laid-Open No. 2007-311584, a mask is absent when scallops are planarized by dry etching. Thus, the surface of a substrate is disadvantageously etched in addition to the side wall of the hole. As a result, the diameter of the hole considerably changes. This may cause a significant reduction in the dimensional accuracy of the hole. In addition, a protection film, which is deposited on the side wall of the hole immediately after performing the Bosch process, is generally deposited nonuniformly and serves as a barrier to dry etching. Therefore, if dry etching is performed without removing the protection film, the scallops on the side wall of the hole cannot be uniformly planarized.

In the method described in Japanese Patent Laid-Open No. 2005-142265, the dimensional accuracy of the hole may be reduced because the hole is deformed by the annealing treatment.

The present invention provides a method for processing a silicon substrate by planarizing irregularities (scallops) on the side wall and thereby forming a hole having high dimensional accuracy and a method for producing a charged-particle beam lens by using the processing method.

### SUMMARY OF THE INVENTION

A method for processing a silicon substrate according to the present invention includes:
a mask layer formation step in which a mask layer is formed on the silicon substrate;
a hole formation step in which a hole is formed in the silicon substrate by alternately repeating:
   (i) an etching step in which plasma etching is performed in a thickness direction of the silicon substrate using the mask layer as a mask; and
   (ii) a deposition step in which a protection film is deposited on an inner wall of the hole formed in the etching step;
a removal step in which the protection film is removed; and
a planarization step in which a side wall of the hole is planarized by etching the inner wall of the hole from which the protection film has been removed.

The mask layer includes a material that withstands the removal step. In the planarization step, the inner wall of the hole is etched using the mask layer as a mask.

Further features of the present invention will become apparent from the following description of exemplary embodiments with reference to the attached drawings.

### BRIEF DESCRIPTION OF THE DRAWINGS

FIGS. 1A to 1D are cross-sectional views illustrating an example of a method for processing a silicon substrate according to the present invention.

FIG. 2 is a cross-sectional view illustrating an example of the structure of a charged-particle beam lens produced according to the present invention.

FIGS. 3A to 3G are cross-sectional views illustrating a method for processing a silicon substrate according to a first example of the present invention in the order of steps.

FIGS. 4A to 4D are cross-sectional views illustrating a method for processing a silicon substrate according to a first example of the present invention in the order of steps.

FIGS. 5A to 5D are cross-sectional views illustrating a method for processing a silicon substrate according to a second example of the present invention in the order of steps.

FIGS. 6A to 6D are cross-sectional views illustrating a method for processing a silicon substrate according to a second example of the present invention in the order of steps.

FIG. 7 is a cross-sectional view schematically illustrating scallops.

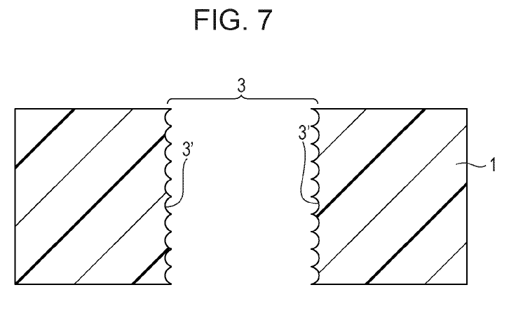

### DESCRIPTION OF THE EMBODIMENTS

Hereafter, the embodiments of the present invention will be described with reference to the attached drawings.

### Method for Processing Silicon Substrate

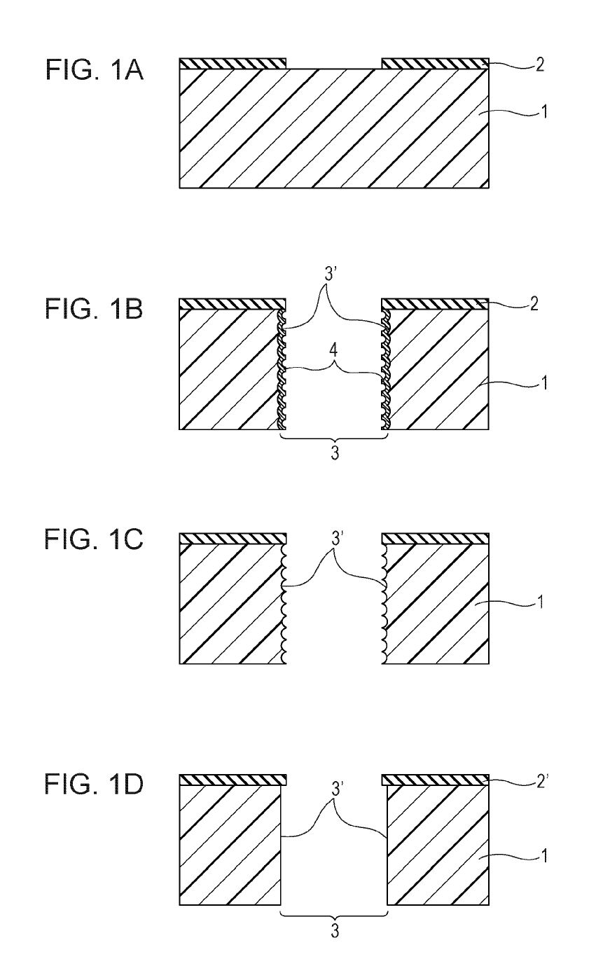

A method for processing a silicon substrate according to the present invention is described with reference to FIGS. 1A to 1D.

### Mask Layer Formation Step

As shown in FIG. 1A, a mask layer 2 having a desired pattern is formed on a silicon substrate.

Although a silicon substrate is used in this embodiment, a processing method similar to the method described herein may be employed even when an SOI (silicon-on-insulator) substrate is used instead.

The mask layer 2 is formed by a photolithography technique or an etching technique. The mask layer 2 is composed of a metal film composed of SiO₂, gold, platinum, chromium, or the like, which has a high selectivity relative to silicon in the Bosch process.

### Hole Formation Step

As shown in FIG. 1B, a hole 3 is formed by the Bosch process using SF₆ as an etching gas and C₄F₈ as a deposition gas. Specifically, the following two steps are repeated alternately: an etching step in which plasma etching is performed in the thickness direction of the silicon substrate 1 using the mask layer 2 as a mask; and a plasma deposition step (hereafter, referred to as “deposition step”) in which a protection film is deposited on the inner wall of a hole formed in the etching step. A side wall 3′ of the hole 3 has irregularities (scallops), and a protection film 4 is deposited on the irregularities. Although the hole penetrates through the silicon substrate 1 in this embodiment, a processing method similar to the method described herein may be employed even when the hole does not penetrate all the way through the silicon substrate 1.

### Protection Film Removal Step (Hereafter, Referred to as “Removal Step”)

As shown in FIG. 10, the protection film 4 is removed. The protection film 4 may be removed by, for example, plasma ashing using oxygen plasma or a method in which a substrate is immersed in a hydrofluoroether-based organic solvent and then subjected to ultrasonic cleaning. In these methods, only the protection film 4 can be selectively removed without etching the silicon substrate 1. As a result, the scallops of the side wall 3′ are exposed. Side Wall Planarization Step (hereafter, referred to as “planarization step”)

As shown in FIG. 1D, the inner wall of the hole 3 is etched to planarize the side wall 3′. The term “inner wall” is herein defined as “side wall 3′ of the hole 3” when the hole 3 is a through-hole as is in this embodiment and as “bottom surface and side wall 3′ of the hole 3” when the hole 3 is not a through-hole. If the protection film 4 still remains in this step, it obstructs etching. However, the protection film 4 has been removed and thereby the scallops on the side wall 3′ have been exposed in the removal step. Thus, the irregularities (scallops) over the entire side wall 3′ can be planarized uniformly. In this step, only the inner wall of the hole 3 is selectively etched without etching the surface of the silicon substrate 1, which causes no reduction in the dimensional accuracy of the hole.

Any known method for etching silicon may be employed as the etching method. Examples of such a method include a dry etching method using SF₆ gas and a wet etching method using tetramethylammonium hydroxide. The dry etching method may be employed because it increases the dimensional accuracy of the hole 3 more.

The method for selectively etching only the inner wall of the hole 3 is, for example, a method in which a mask layer 2′ for the planarization step is formed on the surface of the silicon substrate 1. The mask layer 2′ for the planarization step may be newly formed before the planarization step and after removal of the mask layer 2 used in the hole formation step. Alternatively, the mask layer 2 for the hole formation step may be used also as the mask layer 2′ for the planarization step. When the mask layer 2′ for the planarization step is newly formed, the opening of the mask layer 2′ for the planarization step is formed so as to be aligned with the opening of the hole 3. However, if misaligned, some part of the surface of the silicon substrate 1 may be disadvantageously etched in the planarization step, which reduces the dimensional accuracy of the hole 3. On the other hand, when the mask layer 2 for the hole formation step is used also as the mask layer 2′ for the planarization step, the mask layer 2′ for the planarization step need not be newly formed, in other words, the processing method can be simplified.

Thus, the mask layer 2 for the hole formation step may be composed of a material that withstands the removal step so as to be used also as the mask layer 2′ in the planarization step. For example, when the mask layer 2 for the hole formation step is composed of a material having a resistance to oxygen plasma, such as SiO₂ or a precious metal including gold and platinum, the mask layer 2 can withstand a removal step in which plasma ashing using oxygen plasma is performed. When the mask layer 2 for the hole formation step is composed of an inorganic material such as SiO₂ or chromium, the mask layer 2 can withstand a removal step in which a silicon substrate is immersed in a hydrofluoroether-based organic solvent and subjected to ultrasonic cleaning. When the mask layer 2 is composed of SiO₂, gold, platinum, or chromium, the mask layer 2 can be used also as the mask layer 2′ in a planarization step in which dry-etching using SF₆ gas is performed. When the mask layer 2 is composed of SiO₂, the mask layer 2 can be used also as the mask layer 2′ in a planarization step in which tetramethylammonium hydroxide is used.

The mask layer 2′ for the planarization step may be removed after the planarization step or may be left if needed. When an SOI substrate is used as the silicon substrate 1, the support layer may be removed depending on its application.

The processing method described above achieves uniform planarization of the irregularities (scallops) of the side wall and thereby provides a silicon substrate having a hole having high dimensional accuracy.

### Method for Producing Charged-Particle Beam Lens

Next, a method for producing a charged-particle beam lens according to the present invention is described.

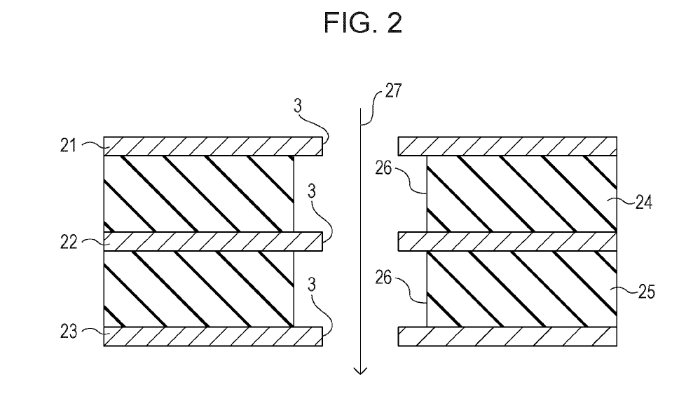

FIG. 2 is a cross-sectional view illustrating an example of the construction of the charged-particle beam lens produced according to the present invention. The charged-particle beam lens includes three electrodes 21, 22, and 23 and two insulated support bodies 24 and 25. The electrodes 21, 22, and 23 are silicon substrates penetrated through by a hole 3 from one side to the other side of each silicon substrate. Although the electrodes 21, 22, and 23 in this embodiment each have a single hole 3, the electrodes 21, 22, and 23 may each have a plurality of holes 3.

The electrodes 21, 22, and 23 are electrically insulated from one another by the support bodies 24 and 25 interposed therebetween. The support bodies 24 and 25 are composed of, for example, Pyrex glass (registered trademark). The support bodies 24 and 25 each have a hole 26 formed in the area that corresponds to the hole 3 of the electrodes 21, 22, and 23, through which a charged-particle beam 27 passes. The support bodies 24 and 25 are arranged so as not to overlap the hole 3. If the distance between the side wall of the hole 3 and the side wall of the hole 26 is short, scattered charged particles, which are part of the charged-particle beam 27, collide with the side wall of the hole 26 and thereby the support bodies 24 and 25 are charged. Consequently, the path of the charged-particle beam 27 is altered due to the change in electric field caused by the electrification. This may deteriorate the optical aberration of the charged-particle beam lens, which is the most important property of the charged-particle beam lens. Thus, the size of the hole 26 needs to be set so as to be sufficiently larger than the area in which the hole 3 of the electrodes 21, 22, and 23 is formed.

The method for producing a charged-particle beam lens according to the present invention includes a step of forming electrodes having a hole penetrating through the silicon substrate from one side to the other side of the silicon substrate by the method for processing a silicon substrate according to the present invention. Specifically, the electrodes 21, 22, and 23 having a hole penetrating through the silicon substrate from one side to the other side of the silicon substrate are formed by, for example, the method shown in FIGS. 1A to 1D.

The hole 26 is formed in the support bodies 24 and 25 by, for example, the following method. A photosensitive dry film is stacked on the surface of the support body, and a mask pattern is formed on the photosensitive dry film by lithography. Then, the support body is subjected to sandblasting to form the hole. After forming the hole, the mask is removed, and the microcracks and burrs present in the processed surface are removed by wet etching and surface polishing.

The electrodes 21, 22, and 23 and the support bodies 24 and 25 are precisely aligned with one another and sequentially stacked and fixed on top of one another. The electrodes 21, 22, and 23 and the support bodies 24 and 25 may be fixed by, for example, applying a silicone-based adhesive having heat resistance around the respective outer peripheries.

The optical aberration of the charged-particle beam lens is highly affected by the dimensional accuracy of the hole 3 of the electrodes 21, 22, and 23. According to the present invention, a hole having high dimensional accuracy is formed by uniformly planarizing the irregularities (scallops). Thus, a charged-particle beam lens having low optical aberration may be realized.

By employing the charged-particle beam lens according to the present invention in a charged-particle beam exposure apparatus, image formation with low optical aberration may be realized and thereby the exposure of a fine pattern may be realized.

### Examples

### Example 1

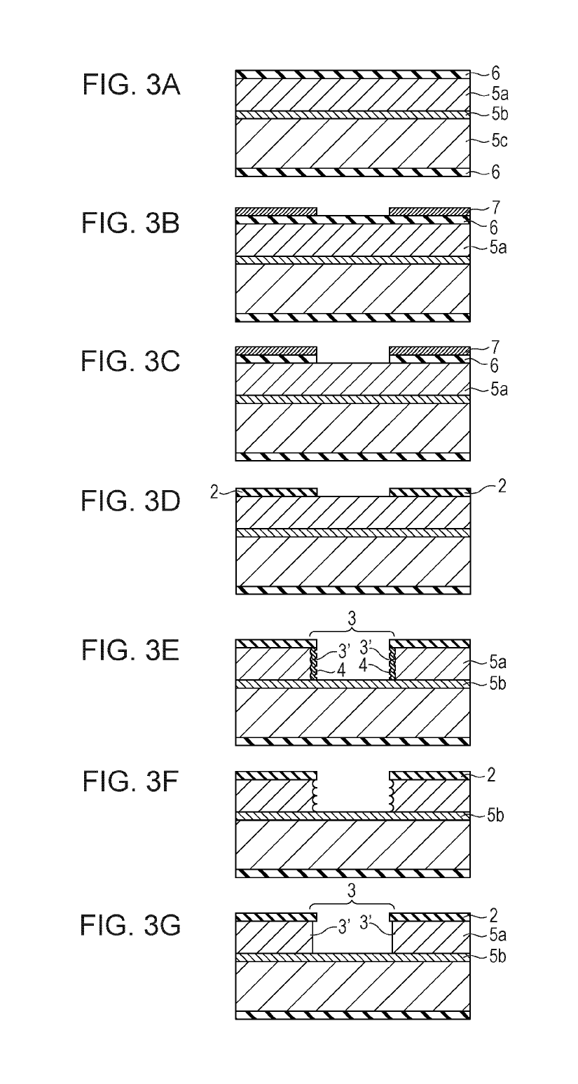

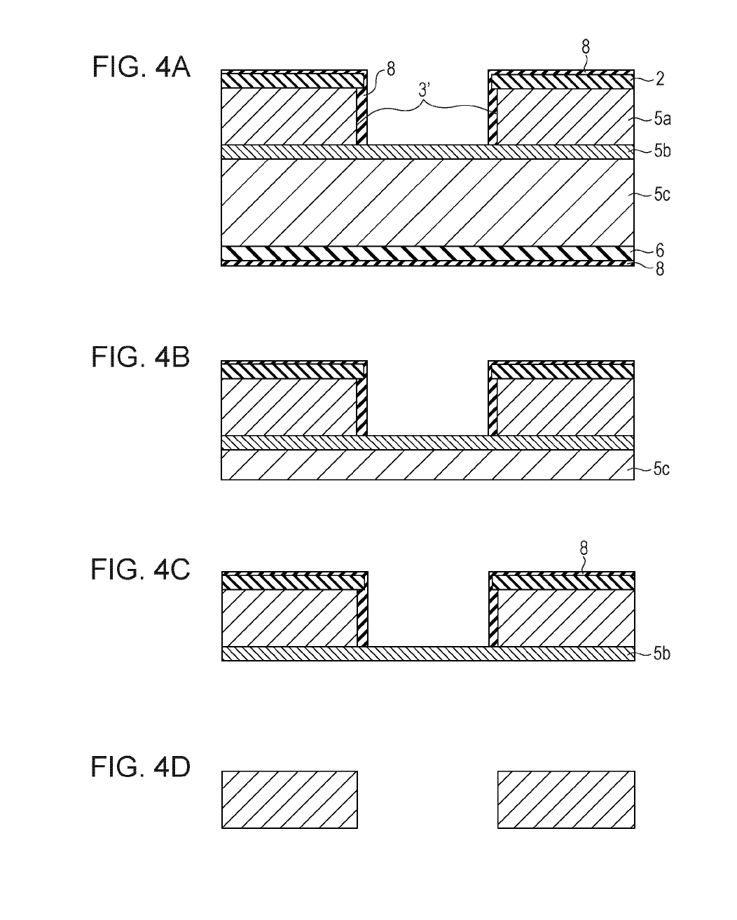

The method for processing a silicon substrate in Example 1 is described with reference to FIGS. 3A to 3G and FIGS. 4A to 4D.

An SOI substrate with a diameter of 4 inches including an active layer 5a with a thickness of 100 μm, a buried oxide (BOX) layer 5b with a thickness of 3 μm, and a support layer 5c with a thickness of 400 μm was prepared. As shown in FIG. 3A, an SiO₂ layer 6 was formed over the entire surface of the SOI substrate by thermal oxidation. The thickness of the SiO₂ layer 6 was 2 μm.

### Mask Layer Formation Step

As shown in FIG. 3B, a resist material was applied to the SiO₂ layer 6 on the active layer 5a so as to have a thickness of 3 μm, and a mask layer 7 composed of the resist material was formed by photolithography. The mask layer 7 had circular openings having a diameter of 50 μm with a pitch of 100 μm.

As shown in FIG. 3C, the SiO₂ layer 6 on the active layer 5a was etched by reactive ion etching using the mask layer 7 as a mask with an inductively coupled plasma (ICP) etching system. The etching gas was CHF₃.

As shown in FIG. 3D, the mask layer 7 was removed and as a result the mask layer 2 for the hole formation step was formed.

### Hole Formation Step

As shown in FIG. 3E, a hole 3 penetrating through the active layer 5a was formed by the Bosch process using the mask layer 2 as a mask with an ICP etching system using SF₆ as an etching gas and C₄F₈ as a deposition gas. In this step, the BOX layer 5b, because being composed of SiO₂, served as an etch stop layer in the Bosch process. The hole 3 had irregularities (scallops) with a size of about 100 nm to about 1000 nm on a side wall 3′ of the hole 3, and a protection film 4 was deposited on the irregularities.

### Removal Step

As shown in FIG. 3F, the protection film 4 was removed by plasma ashing using oxygen plasma with a plasma ashing system. In this step, because SiO₂, of which the mask layer 2 and the BOX layer 5b were composed, and silicon have resistance to oxygen plasma, only the protection film 4 could be selectively removed. In addition, the mask layer 2 could be also used directly as a mask in the following planarization step.

### Planarization Step

As shown in FIG. 3G, the scallops on the side wall 3′ were planarized by reactive ion etching using the mask layer 2 as a mask with an ICP etching system using a mixture gas of SF₆ and CHF₃ under the following conditions: a gas pressure of 0.7 Pa, an ICP power of 500 W, and a bias power of 30 W. In this step, the entire surface of the side wall 3′ could be uniformly planarized since the protection film 4 had been removed in the removal step. Furthermore, the dimensional accuracy of the hole 3 was not reduced because only the side wall 3′ could be selectively etched using the mask layer 2 without etching the surface of the active layer 5a.

### Post-Planarization Step

The substrate was washed with a liquid mixture of sulfuric acid and aqueous hydrogen peroxide and then dried.

Subsequently, all layers other than the active layer, such as the mask layer 2 and the support layer 5c of the SOI substrate, were removed by the following method shown in FIGS. 4A to 4D.

As shown in FIG. 4A, an SiO₂ layer 8 was formed over the entire surface of the SOI substrate by thermal oxidation. The SiO₂ layer 8 was formed so as to have a thickness of 500 nm on the side wall 3′.

As shown in FIG. 4B, the substrate was ground from its support layer 5c side to reduce the thickness of the support layer 5c. Specifically, the substrate was ground by about 300 μm to reduce the thickness of the support layer 5c to 100 μm.

As shown in FIG. 4C, the support layer 5c composed of silicon was removed by wet etching with tetramethylammonium hydroxide (TMAH). In this step, only the support layer 5c could be removed without etching the BOX layer 5b and the SiC₂ layer 8 with TMAH. Although the silicon etch rate in wet etching is generally low, the processing time for the wet etching can be shortened by reducing the thickness of the support layer 5c by grinding in advance as shown in FIG. 4B.

As shown in FIG. 4D, the BOX layer 5b, the mask layer 2, and the SiO₂ layer 8 were removed by wet etching with a buffered hydrofluoric acid (BHF). The resulting substrate was washed with a liquid mixture of sulfuric acid and aqueous hydrogen peroxide and then dried.

### Preparation of Charged-Particle Beam Lens

Then, the charged-particle beam lens shown in FIG. 2 was prepared using the silicon substrate prepared above as an electrode.

Support bodies 24 and 25 were Pyrex glass (registered trademark) discs having a diameter of 4 inches and a thickness of 400 μm. A hole 26 was formed in the support bodies 24 and 25 by the following method. A photosensitive dry film was stacked on the surface of the support body, and a mask pattern was formed on the photosensitive dry film by lithography. Then, the support body was subjected to sandblasting to form the hole. The size of the hole 26 was set so that a distance of 2 mm was maintained between the edge of the hole 26 and the edge of the area in which the hole 3 of the electrodes 21, 22, and 23 was to be formed. After forming the hole 26, the mask was removed, and the microcracks and burrs present in the processed surface were removed by wet etching and surface polishing.

The electrodes 21, 22, and 23, which were the silicon substrates prepared above, and the support bodies 24 and 25 were precisely aligned with one another and sequentially stacked and fixed on top of one another. The electrodes 21, 22, and 23 and the support bodies 24 and 25 were fixed by applying a silicone-based adhesive having heat resistance around the respective outer peripheries.

In Example 1, the electrodes were silicon substrates having a hole having high dimensional accuracy formed by uniformly planarizing the irregularities (scallops). Thus, a charged-particle beam lens having low optical aberration was realized.

By employing the charged-particle beam lens according to the present invention in a charged-particle beam exposure apparatus, image formation with low optical aberration may be realized and thereby the exposure of a fine pattern may be realized.

### Example 2

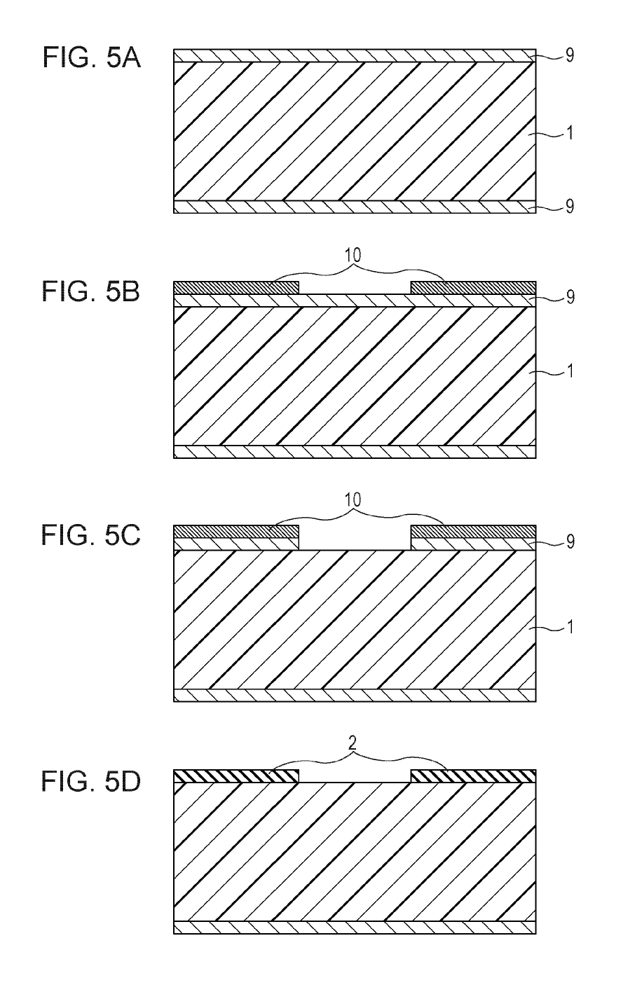

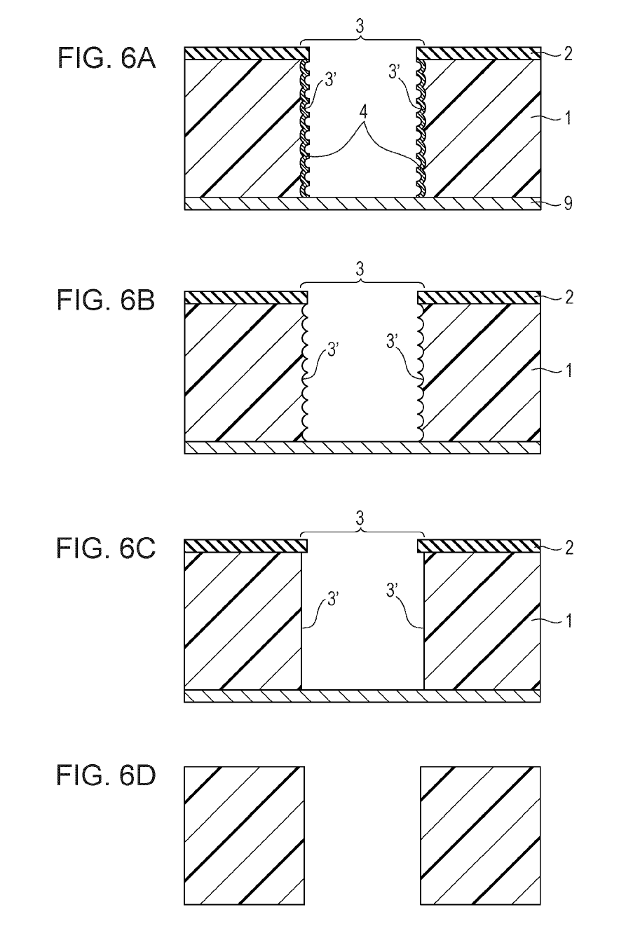

The method for processing a silicon substrate in Example 2 is described with reference to FIGS. 5A to 5D and FIGS. 6A to 6D.

### Mask Layer Formation Step

A silicon substrate having a thickness of 100 μm and a diameter of 4 inches was prepared. As shown in FIG. 5A, a chromium layer 9 was formed on both sides of the silicon substrate 1 by vapor deposition. The thickness of the chromium layer 9 was 200 nm.

As shown in FIG. 5B, a resist material was applied to the chromium layer 9 formed on the front side of the silicon substrate 1 so as to have a thickness of 1 μm, and a mask layer 10 composed of the resist material was formed by photolithography. The mask layer 10 had circular openings having a diameter of 50 μm with a pitch of 100 μm.

As shown in FIG. 5C, the chromium layer 9 formed on the front side of the silicon substrate 1 was etched by reactive ion etching using the mask layer 10 as a mask with an ICP etching system. The etching gas was a mixture gas of O₂, Ar, and Cl₂.

As shown in FIG. 5D, the mask layer 10 was removed and as a result the mask layer 2 for the hole formation step was formed.

### Hole Formation Step

As shown in FIG. 6A, a hole 3 penetrating through the silicon substrate 1 was formed by the Bosch process using the mask layer 2 as a mask under the same conditions as in Example 1. In this step, the chromium layer 9 on the rear side of the silicon substrate 1 served as an etch stop layer in the Bosch process.

### Removal Step

As shown in FIG. 6B, the protection film 4 deposited on the side wall 3′ of the hole 3 was removed using a hydrofluoroether-based organic solvent HFE-7200 (produced by Sumitomo 3M Limited). Specifically, the silicon substrate 1 was immersed in a beaker filled with HFE-7200. The beaker was placed in an ultrasonic cleaning machine to perform ultrasonic cleaning. Then, the silicon substrate 1 was rinsed and dried. In this step, since chromium and silicon have resistance to a hydrofluoroether-based organic solvent, only the protection film 4 could be selectively removed and the mask layer 2 could be directly used also as a mask in the following planarization step.

### Planarization Step

As shown in FIG. 6C, the side wall 3′ was planarized by dry etching using the mask layer 2 as a mask under the same conditions as in Example 1. In this step, the entire part of the side wall 3′ could be uniformly planarized since the protection film 4 had been removed in the removal step. Furthermore, the dimensional accuracy of the hole 3 was not reduced because only the side wall 3′ could be selectively etched using the mask layer 2 without etching the surface of the silicon substrate 1.

### Post-planarization Step

As shown in FIG. 6D, the mask layer 2 and the chromium layer 9 on the rear side of the silicon substrate 1 were removed by wet etching with a common chromium etchant. The substrate was washed with a liquid mixture of sulfuric acid and aqueous hydrogen peroxide and then dried.

In the case where the silicon substrate 1 is thin and this causes difficulties in transportation and handling in equipment, a support substrate may be attached to the rear side of the silicon substrate 1.

As described above, by the method for processing a silicon substrate according to the present invention, irregularities (scallops) on the side wall may be removed and thereby the entire surface of the side wall of the hole may be planarized. In addition, the inner dimensional accuracy of the hole may be maintained because only the inner wall of the hole is selectively etched without etching the surface of the silicon substrate.

According to the method for producing a charged-particle beam lens according to the present invention, a hole having high dimensional accuracy is formed in the silicon substrate. Thus, a charged-particle beam lens having low optical aberration may be realized. By employing the charged-particle beam lens prepared by the method according to the present invention in a charged-particle beam exposure apparatus, image formation with low optical aberration may be realized and thereby the exposure of a fine pattern may be realized.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-207793, filed Sep. 21, 2012, which is hereby incorporated by reference herein in its entirety.

What is claimed is:

1. A method for processing a silicon substrate, the method comprising:
a mask layer formation step in which a mask layer is formed on the silicon substrate;
a hole formation step in which a hole is formed in the silicon substrate by alternately repeating:
(i) an etching step in which plasma etching is performed in a thickness direction of the silicon substrate using the mask layer as a mask; and
(ii) a deposition step in which a protection film is deposited on an inner wall of the hole formed in the etching step;
a removal step in which the protection film is removed; and
a planarization step in which a side wall of the hole is planarized by etching the inner wall of the hole from which the protection film has been removed,
wherein,
the mask layer comprises a material that withstands the removal step, and
in the planarization step, the inner wall of the hole is etched using the mask layer as a mask.

2. The method for processing a silicon substrate according to claim 1,
wherein, in the planarization step, dry-etching is performed.

3. The method for processing a silicon substrate according to claim 1,
wherein, in the hole formation step, the hole is formed so as to penetrate through the silicon substrate from one side to the other side of the silicon substrate.

4. The method for processing a silicon substrate according to claim 1, further comprising, subsequent to the planarization step, a step of removing the mask layer.

5. The method for processing a silicon substrate according to claim 1,
wherein,
the silicon substrate is a silicon-on-insulator (SOI) substrate, and
in the hole formation step, the hole is formed in an active layer of the silicon-on-insulator (SOI) substrate,
the method further comprising, subsequent to the planarization step, a step of removing all layers other than the active layer of the silicon-on-insulator (SOI) substrate.

6. A method for producing a charged-particle beam lens including a plurality of electrodes and a support body interposed between the plurality of electrodes,
the plurality of electrodes being penetrated through by a hole from one side to the other side of each of the plurality of electrodes, the hole being formed by a method for processing a silicon substrate, the method comprising:
a mask layer formation step in which a mask layer is formed on the silicon substrate;
a hole formation step in which a hole is formed in the silicon substrate by alternately repeating:
(i) an etching step in which plasma etching is performed in a thickness direction of the silicon substrate using the mask layer as a mask; and
(ii) a deposition step in which a protection film is deposited on an inner wall of the hole formed in the etching step;
a removal step in which the protection film is selectively removed; and
a planarization step in which a side wall of the hole is planarized by selectively etching the inner wall of the hole from which the protection film has been removed.

7. The method for producing a charged-particle beam lens according to claim 6,
wherein the mask layer comprises a material that withstands the removal step, and
in the planarization step, the inner wall of the hole is etched using the mask layer as a mask.
